(19) United States
(12) Patent Application Publication
(10) Pub. No.: US 2010/0164604 A1
(43) Pub. Date: Jul. 1, 2010

(54) FUSE CIRCUIT AND LAYOUT DESIGNING METHOD THEREOF

(76) Inventor: Jeong-Joo Park, Anyang-si (KR)

Correspondence Address: SHERR & VAUGHN, PLLC, 620 HERNDON PARKWAY, SUITE 320, HERNDON, VA, 20170, US

(21) Appl. No.: 12/647,511

(22) Filed: Dec. 27, 2009

(30) Foreign Application Priority Data
Dec. 30, 2008 (KR) 10-2008-0137601

(51) Int. Cl. H01H 85/00; H01L 21/768

(52) U.S. Cl. 327/525; 438/601; 257/E21.592

(57) ABSTRACT

A fuse circuit for sensing a fuse connected state and layout designing method thereof are disclosed. Embodiments include a fuse program control unit providing a fuse open voltage in response to a program signal, a fuse cell unit configured to use a contact resistor connecting a node supplied with the fuse open voltage and a node supplied with a fuse connection voltage as a fuse, the fuse cell unit outputting a state information of the contact resistor in response to the fuse open voltage, and a fuse sensing unit outputting a fuse data signal corresponding to the state information of the contact resistor in response to a read signal. Accordingly, embodiments reduce a layout size of the fuse circuit.

The present application claims priority under 35 U.S.C. 119 to Korean Patent Application No. 10-2008-0137601 (filed on Dec. 30, 2008), which is hereby incorporated by reference in its entirety.

### BACKGROUND

Generally, a fuse plays a role in disconnecting two electrodes using a large current. According to a related art, two electrodes are electrically disconnected by a fuse of a poly resistor when a current above a certain threshold is applied to the resistor.

For instance, referring to FIG. 1, a fuse circuit according to a related art consists of a fuse program control unit 10, a fuse cell unit 12 and a fuse sensing unit 14. The fuse program control unit 10 switches a transfer of a high voltage VPP by a program signal PRGM. In particular, if the program signal PRGM is enabled, the high voltage VPP is applied to the fuse cell unit 12 via a node N1.

The fuse cell unit 12 includes a poly resistor PR provided between two nodes N1 and N2. Alternatively, the fuse cell unit 12 can include a metal resistor instead of the poly resistor PR. If the high voltage VPP is applied to the node N1 via the fuse program control unit 10, the poly resistor PR is melted to open the two nodes N1 and N2.

The fuse sensing unit 14 senses whether the two nodes N1 and N2 are shorted or open in response to a read signal RD and then outputs a fuse data signal FUSE_DATA.

Meanwhile, an anti-fuse exists in a concept opposite to the fuse and plays a role in connecting two electrodes through a large current. An anti-fuse according to a related art consists of a capacitor. If a voltage higher than a breakdown voltage is applied to a pair of electrodes, a pair of the electrodes are shorted by the capacitor.

For instance, referring to FIG. 2, a switching circuit according to a related art, which uses an anti-fuse, consists of an anti-fuse program control unit 20, an anti-fuse cell unit 22 and an anti-fuse sensing unit 24. The anti-fuse program control unit 20 and the anti-fuse sensing unit 24 can have the same configurations of the fuse program control unit 10 and the fuse sensing unit 14, of which details are omitted from the following description.

The anti-fuse cell unit 22 consists of a capacitor C connected between two nodes N3 and N4. The capacitor C can be replaced by a MOS transistor. If a high voltage VPP is applied to the node N3 via the anti-fuse program control unit 20, an insulating layer of the capacitor C is broken to short the two nodes N3 and N4.

Thus, according to the related art, a poly or metal resistor is used as a fuse. A capacitor or MOS transistor is used as an anti-fuse. And, a fuse data signal indicating whether the fuse or the anti-fuse is shorted is outputted by programming.

However, the poly or metal resistor used as the fuse and the capacitor or MOS transistor used as the anti-fuse occupy relatively large areas in a highly integrated semiconductor device, respectively. Specifically, Since a plurality of the circuits having the configuration shown in FIG. 1 or FIG. 2 are provided to a general semiconductor device, the area occupied by the fuse or anti-fuse circuit in the semiconductor device may become a critical issue.

### SUMMARY

Embodiments relate to a fuse circuit, and more particularly, to a fuse circuit and layout designing method thereof. Although embodiments are suitable for a wide scope of applications, they are particularly suitable for sensing a fuse connection state. Embodiments relate to a fuse circuit and layout designing method thereof, by which a layout size can be reduced.

Embodiments relate to a fuse circuit which may include a fuse program control unit providing a fuse open voltage in response to a program signal, a fuse cell unit configured to use a contact resistor connecting a node supplied with the fuse open voltage and a node supplied with a fuse connection voltage as a fuse, the fuse cell unit outputting a state information of the contact resistor in response to the fuse open voltage, and a fuse sensing unit outputting a fuse data signal corresponding to the state information of the contact resistor in response to a read signal.

If the fuse open voltage is supplied by the fuse program control unit, the fuse cell unit may be floated. If the fuse open voltage is not supplied, the fuse cell unit provides the fuse connection voltage to the fuse sensing unit. The contact resistor may be formed of a material melted if the fuse open voltage is applied. The fuse sensing unit may output the fuse data signal corresponding to a logic level state of the fuse open voltage or the fuse connection voltage in response to the read signal. The fuse open voltage may correspond to a voltage having a level equal to or greater than a power source voltage. And, the fuse connection voltage corresponds to a ground voltage.

Embodiments relate to a fuse circuit includes a fuse program control unit providing a fuse open voltage in response to a program signal, a fuse cell unit configured to use a via resistor connecting a node supplied with the fuse open voltage and a node supplied with a fuse connection voltage as a fuse, the fuse cell unit outputting a state information of the via resistor in response to the fuse open voltage, and a fuse sensing unit outputting a fuse data signal corresponding to the state information of the via resistor in response to a read signal.

If the fuse open voltage is supplied by the fuse program control unit, the fuse cell unit may be floated. If the fuse open voltage is not supplied, the fuse cell unit provides the fuse connection voltage to the fuse sensing unit. The via resistor may be formed of a material melted if the fuse open voltage is applied. The fuse sensing unit may output the fuse data signal corresponding to a logic level state of the fuse open voltage or the fuse connection voltage in response to the read signal. The fuse open voltage may correspond to a voltage having a level equal to or greater than a power source voltage and wherein the fuse connection voltage corresponds to a ground voltage.

Embodiments relate to a method of designing a layout of a fuse circuit, which senses a state of a fuse using a fuse open voltage and a fuse connection voltage, includes the steps of forming an active region, forming a first line for supplying the fuse open voltage and a second line for supplying the fuse connection voltage on the active region, forming a first contact as the fuse between the active region and the first line, and forming a second contact between the active region and the second line, wherein information for sensing a state of the fuse is outputted through the first line.

The contact resistor may be formed of a material melted if the fuse open voltage is applied to the first line. The active region may be a p type active region formed in a p type well.

The fuse open voltage may correspond to a voltage having a level equal to or greater than a power source voltage and wherein the fuse connection voltage corresponds to a ground voltage.

Embodiments also relate to a method of designing a layout of a fuse circuit, which senses a state of a fuse using a fuse open voltage and a fuse connection voltage, includes the steps of forming a first line for supplying the fuse open voltage and a second line for supplying the fuse connection voltage and forming a via as the fuse between the first line and the second line, wherein information for sensing a state of the fuse is outputted through the first line.

The via may be formed of a material melted if the fuse open voltage is applied to the first line. The fuse open voltage may correspond to a voltage having a level equal to or greater than a power source voltage and wherein the fuse connection voltage corresponds to a ground voltage.

### DRAWINGS

FIG. 1 is a circuit block diagram of a fuse circuit according to a related art.

FIG. 2 is a circuit block diagram of an anti-fuse circuit according to a related art.

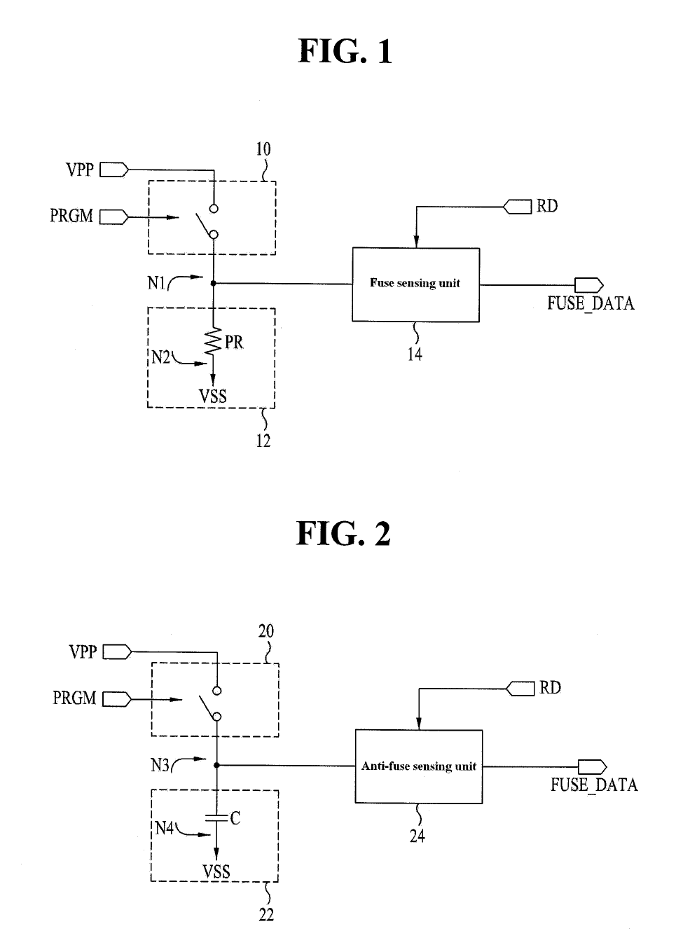

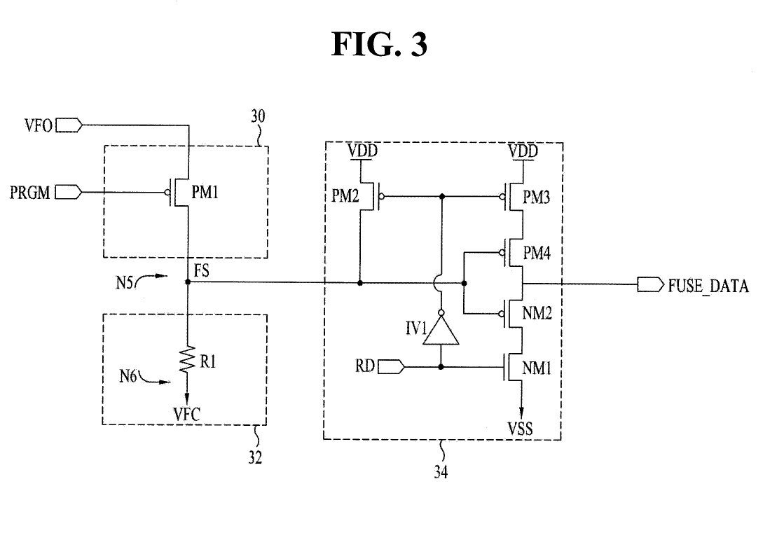

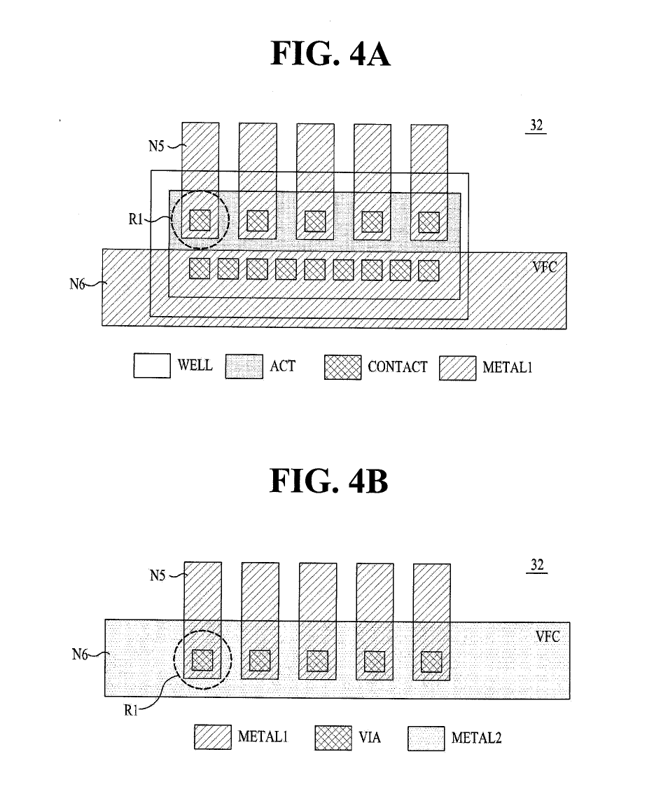

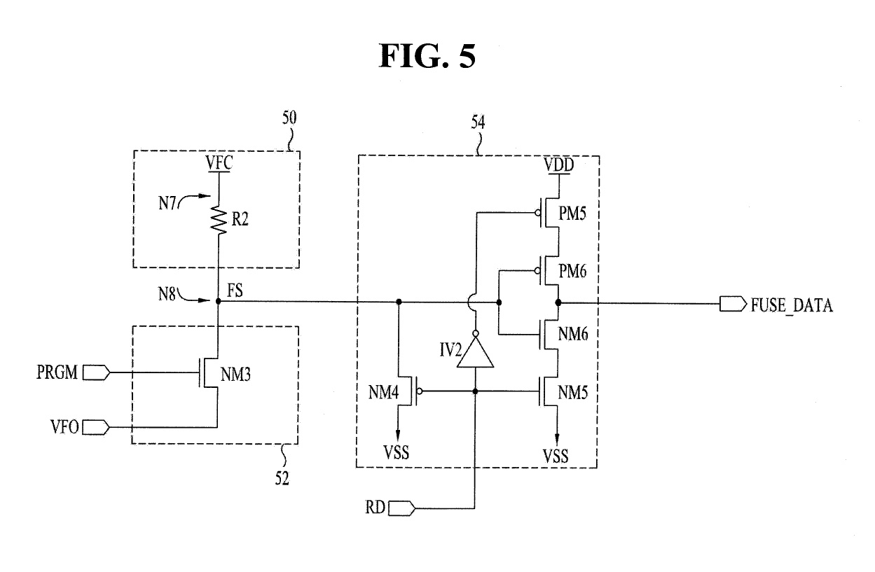

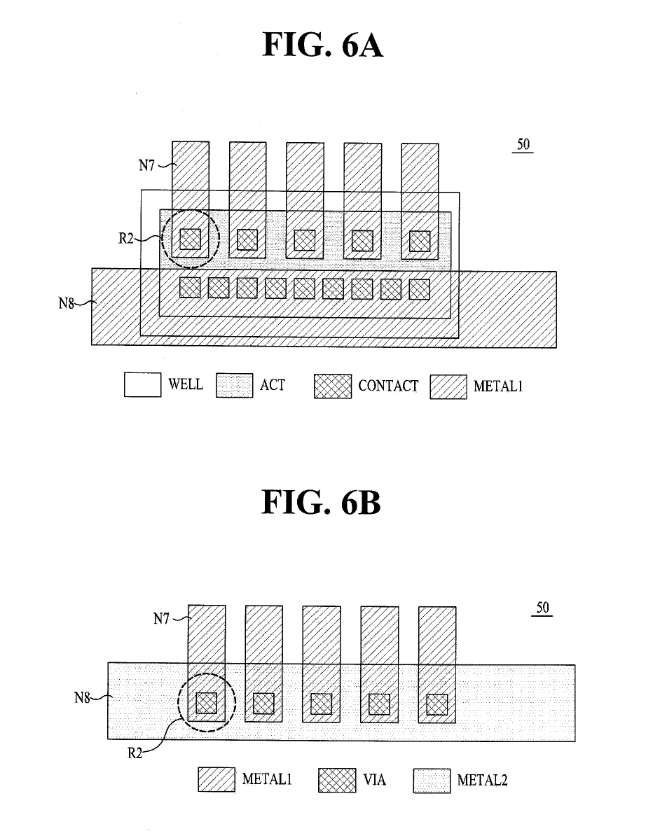

Example FIG. 3 is a circuit block diagram of a fuse circuit according to embodiments.

Example FIG. 4A and example FIG. 4B are diagrams of a layout of a fuse cell unit 32 shown in example FIG. 3.

Example FIG. 5 is a circuit block diagram of a fuse circuit according to embodiments.

Example FIG. 6A and example FIG. 6B are diagrams of a layout of a fuse cell unit 50 shown in example FIG. 5.

### DESCRIPTION

Embodiments relate to a fuse circuit, in which an area is minimized using a contact or via for connecting two lines electrically as a fuse. In particular, referring to example FIG. 3, a fuse circuit according to embodiments may include a fuse program control unit 30, a fuse cell unit 32 and a fuse sensing unit 34.

The fuse program control unit 30 switches a transfer of a fuse open voltage VFO by a program signal PRGM and can include a PMOS transistor PM1 configured to supply the fuse open voltage VFO to a node N5 in response to the program signal PRGM. In this case, the fuse open voltage VFO has a potential capable of melting a fuse resistor R1 provided to the fuse cell unit 32, which will be described later. The fuse open voltage VFO may correspond to a voltage VPP at a level higher than that of a power source voltage VDD.

When the program signal PRGM is enabled, the above configured program control unit 30 supplies the fuse open voltage VFO to the fuse sensing unit 34 via the node N5. The fuse cell unit 32 switches a transfer of a fuse connection voltage VFC in response to the fuse open voltage VFO and can include a fuse resistor R1 connected between the two nodes N5 and N6. In this case, the fuse connection voltage VFC may correspond to a voltage at a level lower than that of the power source voltage VDD, and more particularly, to a ground voltage VSS. Moreover, the fuse resistor R1 may include a contact or via that is melted by the fuse connection voltage VFC.

When the fuse open voltage VFO is applied to the node N5 via the fuse program control unit 30, the above configured fuse cell unit 32 is floated. When the fuse open voltage VFO is not applied to the node N5, the fuse connection voltage VFC is supplied to the fuse sensing unit 34 via the node N5.

The fuse sensing unit 34 may include an inverter IV1 outputting a fuse data signal FUSE_DATA corresponding to a signal provided by the node N5, i.e., a fuse state signal FS in response to a read signal RD. The inverter IV1 inverts a phase of the read signal RD. A PMOS transistor PM2 supplies a power source voltage VDD to the node N5 in response to the output of the inverter IV1. A PMOS transistor PM3 supplies the power source voltage VDD in response to the output of the inverter IV1. A PMOS transistor PM4 supplies the power source voltage VDD supplied from the PMOS transistor PM3 as a fuse data signal FUSE_DATA in response to the fuse state signal FS. An NMOS transistor NM1 supplies a ground voltage VSS in response to the read signal RD. Finally, an NMOS transistor NM2 outputs the ground voltage VSS supplied from the NMOS transistor NM1 as a fuse data signal FUSE_DATA in response to the fuse state signal FS.

When the fuse state signal FS corresponds to the level of the fuse open voltage VFO, the above configured fuse sensing unit 34 outputs a fuse data signal FUSE_DATA at a logic low level. When the fuse state signal FS corresponds to the level of the fuse connection voltage VFC, the above configured fuse sensing unit 34 outputs a fuse data signal FUSE_DATA at a logic high level.

The fuse cell unit 32 shown in example FIG. 3 can have the layout structure shown in example FIG. 4A or example FIG. 4B. Referring to example FIG. 4A, a well area WELL may be formed. An active region ACT may be formed in the well area WELL. A plurality of contacts CONTACT may be formed in the active region ACT by forming two rows. A plurality of metal lines METAL1 may be formed on the contacts CONTACT to correspond to two nodes N5 and N6, respectively. In this case, the contact CONTACT provided between the active region ACT and the metal line METAL1 corresponding to the node N5 to connect them together electrically may be configured to correspond to the fuse resistor R1. Each of the well area WELL and the active region ACT may be a P type.

Generally, the metal resistor may have a resistance of about 0.1 ohm and a contact resistance connected to the active region ranges from several ohms to tens of ohms. Therefore, the contact CONTACT shown in example FIG. 4A can be used as a fuse resistor R1. For reference, the contact CONTACT provided between the active region ACT and the metal line METAL1 corresponding to the node N5 may be formed to have a wire layout size to supply sufficient current to the fuse resistor R1.

For another example of the fuse cell unit 32, as shown in example FIG. 4B, a fuse resistor R1 can be formed as a via VIA. Referring to example FIG. 4B, a metal line METAL1 corresponding to a node N5 may be formed. A via VIA may be formed on the metal line METAL1 Another metal line METAL2 corresponding to a node N6 may be formed on the via VIA. Thus, the two metal lines METAL1 and METAL2 may be electrically connected to each other through the via VIA.

The structure, in which the via VIA may be used as the fuse resistor R1, does not use the active region ACT, which is advantageous in having a layout size smaller than that of the structure using the contact CONTACT shown in example FIG. 4A. Yet, with respect to the layout size, since the via VIA has a resistance smaller than that of the active contact CONTACT, the via VIA needs to have a sufficient layout size to allow it to be cut by fusing.

A fuse circuit according to embodiments can be configured in a manner shown in example FIG. 5. Referring to example FIG. 5, a fuse circuit according to embodiments may include a fuse cell unit 50, a fuse program control unit 52 and a fuse sensing unit 54.

The fuse cell unit 50 can include a fuse resistor R2 provided between two nodes N7 and N8. When a fuse open voltage VFO is applied to the node N8 through the fuse program control unit 52, the fuse cell unit 50 is floated. When a fuse open voltage VFO is not applied, the fuse cell unit 50 supplies a fuse connection voltage VFC to the fuse sensing unit 54 through the node N8.

The fuse program control unit 52 may include an NMOS transistor NM3 for supplying a fuse open voltage VFO to the node N8 in response to a program signal PRGM. If the program signal PRGM is enabled, the fuse program control unit 52 supplies the fuse open voltage VFO to the fuse sensing unit 54 through the node N8.

The fuse sensing unit 54 can include an inverter IV2 which inverts a phase of a read signal RD. An NMOS transistor NM4 supplies a ground voltage VSS to a node N8 in response to an output of the inverter IV2. An NMOS transistor NM5 supplies the ground voltage VSS in response to the output of the inverter IV2. An NMOS transistor NM6 outputs the ground voltage VSS supplied by the NMOS transistor NM5 as a fuse data signal FUSE_DATA in response to a signal provided by a node N5, i.e., a fuse state signal FS. A PMOS transistor PM5 supplies a power source voltage VDD in response to the read signal RD. Finally, a PMOS transistor PM6 outputs the power source voltage VDD supplied by the PMOS transistor PM5 as a fuse data signal FUSE_DATA in response to the fuse state signal FS.

When the fuse state signal FS corresponds to the level of the fuse open voltage VFO, the above configured fuse sensing unit 54 outputs a fuse data signal FUSE_DATA at a logic low level. When the fuse state signal FS corresponds to the level of the fuse connection voltage VFC, the above configured fuse sensing unit 54 outputs a fuse data signal FUSE_DATA at a logic high level.

The fuse cell unit 50 shown in example FIG. 5 can have the layout structure shown in example FIG. 6A or example FIG. 6B. Referring to example FIG. 6A, a well area WELL may be formed. An active region ACT may be formed in the well area WELL. A plurality of contacts CONTACT may be formed in the active region ACT by forming two rows. A plurality of metal lines METAL1 may be formed on the contacts CONTACT to correspond to two nodes N7 and N8, respectively. In this case, the contact CONTACT provided between the active region ACT and the metal line METAL1 corresponding to the node N7 to connect them together electrically may be configured to correspond to the fuse resistor R1. Each of the well area WELL and the active region ACT may be a P type.

Referring to example FIG. 6B, a metal line METAL1 corresponding to a node N5 may be formed. A via VIA may be formed on the metal line METAL1. Another metal line METAL2 corresponding to a node N6 may be formed on the via VIA. Thus, the two metal lines METAL1 and METAL2 may be electrically connected to each other through the via VIA.

Accordingly, embodiments provide the following effects and/or advantages. First of all, embodiments may use a contact or via for connecting two lines electrically as a fuse, thereby reducing a layout size occupied by the fuse circuit. Secondly, embodiments may use a contact or via for connecting two lines electrically as a fuse without using a separately added mask, thereby reducing fabrication time compared to a related art fuse circuit using a poly resistor of capacitor.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a fuse program control unit configured to provide a fuse open voltage in response to a program signal;
a fuse cell unit configured to use a contact resistor connecting a node supplied with the fuse open voltage and a node supplied with a fuse connection voltage as a fuse, the fuse cell unit outputting state information of the contact resistor in response to the fuse open voltage; and
a fuse sensing unit configured to output a fuse data signal corresponding to the state information of the contact resistor in response to a read signal.

2. The apparatus of claim 1, wherein if the fuse open voltage is supplied by the fuse program control unit, the fuse cell unit is floated.

3. The apparatus of claim 2, wherein if the fuse open voltage is not supplied by the fuse program control unit, the fuse cell unit provides the fuse connection voltage to the fuse sensing unit.

4. The apparatus of claim 2, wherein the contact resistor is formed of a material melted if the fuse open voltage is applied.

5. The apparatus of claim 3, wherein the fuse sensing unit outputs the fuse data signal corresponding to a logic level state of one of the fuse open voltage and the fuse connection voltage in response to the read signal.

6. The apparatus of claim 1, wherein the fuse open voltage corresponds to a voltage having a level at least equal to a power source voltage and wherein the fuse connection voltage corresponds to a ground voltage.

7. An apparatus comprising:
a fuse program control unit configured to provide a fuse open voltage in response to a program signal;
a fuse cell unit configured to use a via resistor connecting a node supplied with the fuse open voltage and a node supplied with a fuse connection voltage as a fuse, the fuse cell unit outputting state information of the via resistor in response to the fuse open voltage; and
a fuse sensing unit configured to output a fuse data signal corresponding to the state information of the via resistor in response to a read signal.

8. The apparatus of claim 7, wherein if the fuse open voltage is supplied by the fuse program control unit, the fuse cell unit is floated.

9. The apparatus of claim 8, wherein if the fuse open voltage is not supplied by the fuse program control unit, the fuse cell unit provides the fuse connection voltage to the fuse sensing unit.

10. The apparatus of claim 8, wherein the via resistor is formed of a material melted if the fuse open voltage is applied.

11. The apparatus of claim 9, wherein the fuse sensing unit outputs the fuse data signal corresponding to a logic level state of one of the fuse open voltage and the fuse connection voltage in response to the read signal.

12. The apparatus of claim 8, wherein the fuse open voltage corresponds to a voltage having a level at least as great as a power source voltage and wherein the fuse connection voltage corresponds to a ground voltage.

13. A method comprising:
forming an active region in a semiconductor;
forming a first line for supplying a fuse open voltage and a second line for supplying a fuse connection voltage on the active region;
forming a first contact as a fuse between the active region and the first line; and
forming a second contact between the active region and the second line,
wherein information for sensing a state of the fuse is outputted through the first line.

14. The method of claim 13, wherein the contact resistor is formed of a material melted if the fuse open voltage is applied to the first line.

15. The method of claim 13, wherein the active region is a p type active region formed in a p type well.

16. The method of claim 13, wherein the fuse open voltage corresponds to a voltage having a level equal to or greater than a power source voltage and wherein the fuse connection voltage corresponds to a ground voltage.

17. A method comprising:
forming a first line for supplying a fuse open voltage and a second line for supplying a fuse connection voltage in a semiconductor device; and
forming a via as a fuse between the first line and the second line,
wherein information for sensing a state of the fuse is outputted through the first line.

18. The method of claim 17, wherein the via is formed of a material melted if the fuse open voltage is applied to the first line.

19. The layout method of claim 17, wherein the fuse open voltage corresponds to a voltage having a level at least as great as a power source voltage.

20. The layout method of claim 17, wherein the fuse connection voltage corresponds to a ground voltage.
